(19) United States
(12) Patent Application Publication
(10) Pub. No.: US 2013/0057324 A1
(43) Pub. Date: Mar. 7, 2013

(54) CIRCUIT FOR CLEARING COMPLEMENTARY METAL OXIDE SEMICONDUCTOR INFORMATION

(71) Applicants: YI-XIN TU, Shenzhen City (CN); JIN-LIANG XIONG, Shenzhen City (CN); HAI-QING ZHOU, Shenzhen City (CN)

(72) Inventors: YI-XIN TU, Shenzhen City (CN); JIN-LIANG XIONG, Shenzhen City (CN); HAI-QING ZHOU, Shenzhen City (CN)

(73) Assignees: HON HAI PRECISION INDUSTRY CO., LTD., Tu-Cheng (CN); HONG FU JIN PRECISION INDUSTRY (ShenZhen) Co., LTD., Shenzhen City (CN)

(21) Appl. No.: 13/305,127

(22) Filed: Nov. 28, 2011

(30) Foreign Application Priority Data
Sep. 6, 2011 (CN) 201110262077.2

(51) Int. Cl. H03L 7/00

(52) U.S. Cl. 327/143

(57) ABSTRACT

A circuit for clearing complementary metal oxide semiconductor (CMOS) information of a CMOS chip includes a battery, first to fifth resistors, first and second electronic switches, a switching unit, and first and second diodes. The circuit can clear information of the CMOS chip when one or more switches are activated.

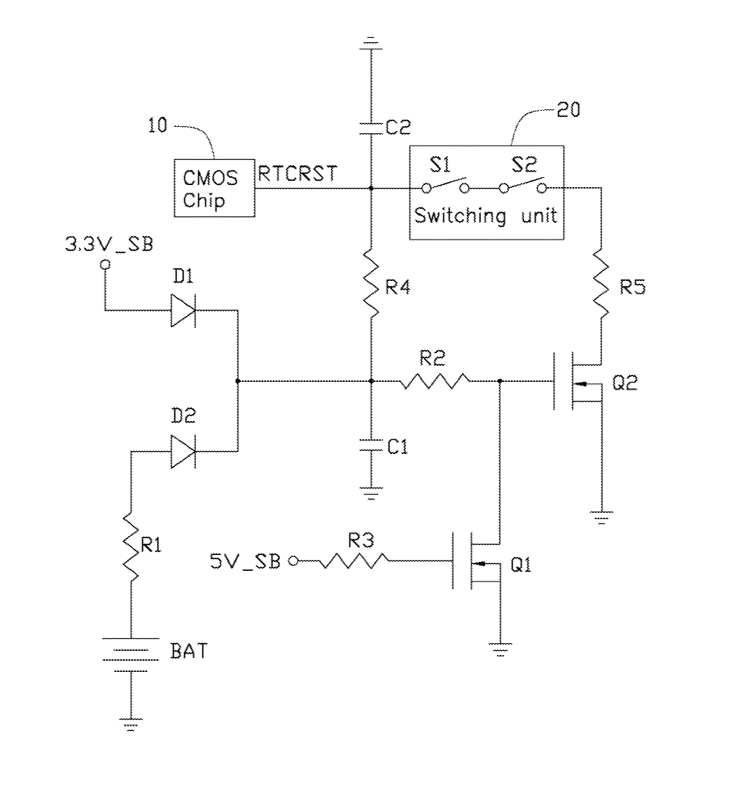

### BACKGROUND

1. Technical Field

The present disclosure relates to a circuit for clearing complementary metal oxide semiconductor (CMOS) information.

2. Description of Related Art

Jumpers are often used on a motherboard to maintain the power supply to a south bridge chip thus safeguarding the CMOS information stored in the south bridge chip. Furthermore, the jumpers may be set to invoke a function to clear the CMOS information in the south bridge chip, and reinstate default settings for the BIOS, which will allow the computer to boot if an error in the BIOS setting occurs, or if the CMOS boot password is forgotten. However, using a jumper to clear the CMOS information is time-consuming and inefficient because the computer enclosure must be taken apart to clear the CMOS information.

### BRIEF DESCRIPTION OF THE DRAWING

Many aspects of the embodiments can be better understood with reference to the drawing. The components in the drawing are not necessarily drawn to scale, the emphasis instead being placed upon clearly illustrating the principles of the present embodiments.

The FIGURE is a circuit diagram of an exemplary embodiment of a circuit for clearing information from a complementary metal oxide semiconductor.

### DETAILED DESCRIPTION

The disclosure, including the accompanying drawing, is illustrated by way of examples and not by way of limitation. It should be noted that references to “an” or “one” embodiment in this disclosure are not necessarily to the same embodiment, and such references mean at least one.

Referring to the FIGURE, an exemplary embodiment of a circuit for clearing information from a complementary metal oxide semiconductor (CMOS) chip 10 on a motherboard of a computer system includes five resistors R1 to R5, two capacitors C1 and C2, two diodes D1 and D2, two n-channel field effect transistors (FETs) Q1 and Q2, a switching unit 20, and a battery BAT. In this embodiment, the switching unit 20 includes two switches S1 and S2 connected in series.

An anode of the diode D1 is connected to a power source (first standby power 3.3V_SB). A cathode of the diode D1 is connected to a cathode of the diode D2. An anode of the diode D2 is connected a positive terminal of the battery BAT through the resistor R1. A negative terminal of the battery BAT is grounded. The cathode of the diode D1 is further connected to a drain of the FET Q1 through the resistor R2. The drain of the FET Q1 is further connected to a gate of the FET Q2. A gate of the FET Q1 is connected to another power source (second standby power 5V_SB) through the resistor R3. Both sources of the FETs Q1 and Q2 are grounded.

The cathode of the diode D1 is further grounded through the capacitor C1, and also grounded through the resistor R4 and the capacitor C2 which are connected in series. A node between the resistor R4 and the capacitor C2 is connected to a drain of the FET Q2 through the switches S1 and S2, and the resistor R5, in that order. The node is further connected to a reset terminal RTCRST of the CMOS chip 10.

According to the characteristics of the particular CMOS chip, when the reset terminal RTCRST of the CMOS chip 10 receives a low level signal, the input information of the CMOS chip 10 is cleared.

When the computer system is powered on, the first standby power 3.3V_SB and the second standby power 5V_SB output a logic 1 high level voltage. The diode D2 is turned off because the voltage of the first standby power 3.3V_SB is larger than the voltage of the battery BAT. In addition, the reset terminal RTCRST of the CMOS chip 10 receives the voltage of the first standby power 3.3V_SB through the resistor R4. Furthermore, because of the second standby power 5V_SB, the FET Q1 is turned on, and therefore the FET Q2 is turned off. In this situation, even if the switches S1 and S2 are pressed, the reset terminal RTCRST of the CMOS chip 10 cannot receive a low level signal. In other words, when the computer system is powered on, the information of the CMOS chip 10 cannot be cleared.

When the computer system is powered off, the first standby power 3.3V_SB and the second standby power 5V_SB do not output voltages. The diode D1 and the FET Q1 are turned off, and the diode D2 is turned on. At this time, the battery BAT outputs a voltage to the gate of the FET Q2 through the resistor R1, the diode D2, and the resistor R2 in that order. The FET Q2 is turned on. In addition, the battery BAT outputs a voltage to the reset terminal RTCRST of the CMOS chip 10 through the diode D2 and the resistor R4 in series. At this time, when the switches S1 and S2 are pressed, the reset terminal RTCRST of the CMOS chip 10 is grounded through the resistor R5 and the FET Q2. The voltage that the reset terminal RTCRST receives is equal to the voltage difference between the two terminals of the resistor R5. In the embodiment, a resistance of the resistor R5 is much, much less than the sum of the resistances of the resistors R1 and R4, such that the voltage difference at the node between switch S2 and resistor R5 is almost zero. As a result, the reset terminal RTCRST receives a low level signal. Therefore, the information stored in the CMOS chip 10 is cleared.

In the embodiment, the switches S1 and S2 can be exposed through an enclosure of the computer system for easy user access. As a result, users can clear the information of the CMOS chip 10 without disassembling the enclosure. Furthermore, users need to press the two switches S1 and S2 simultaneously to clear information from the CMOS chip 10, which tends to avoid incorrect operation. In other embodiments, the two switches S1 and S2 can be replaced by any switching unit. The switching unit can include a single switch, or three or more switches connected in series. Furthermore, the FETs Q1 and Q2 act as simple electronic switches in this embodiment therefore the FETs Q1 and Q2 can be replaced by any other electronic or transistor switch.

The foregoing description of the exemplary embodiments of the disclosure has been presented only for the purposes of illustration and description and is not intended to be exhaustive or to limit the disclosure to the precise forms disclosed. Many modifications and variations are possible in the light of everything above. The embodiments were chosen and described in order to explain the principles of the disclosure and their practical application so as to enable others of ordinary skill in the art to utilize the disclosure and various embodiments with such modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than by the foregoing description and the exemplary embodiments described therein.

What is claimed is:

1. A circuit for clearing complementary metal oxide semiconductor (CMOS) information of a CMOS chip, the circuit comprising:
a battery;
first to fourth resistors;
first and second electronic switches each comprising a control terminal, a first terminal, and a second terminal;
a switching unit; and
first and second diodes, wherein an anode of the first diode is connected to a first standby power, a cathode of the first diode is connected to a cathode of the second diode, an anode of the second diode is connected to a positive terminal of the battery through the first resistor, a negative terminal of the battery is grounded, the cathode of the second diode is connected to the first terminal of the first electronic switch and a control terminal of the second electronic switch, a control terminal of the first electronic switch is connected to a second standby power through the second resistor, the second terminals of the first and second electronic switches are grounded, the cathode of the second diode is further connected to the first terminal of the second electronic switch through the third resistor, the switching unit, and the fourth resistor in that order, a node between the third resistor and the switching unit is connected to a reset terminal of the CMOS chip;
wherein the first and second electronic switches are turned on in response to the control terminals receiving high level voltage signals.

2. The circuit of claim 1, wherein the switching unit comprises two switches connected in series.

3. The circuit of claim 1, further comprising a capacitor, wherein the cathode of the second diode is grounded through the capacitor.

4. The circuit of claim 1, further comprising a capacitor, wherein the node between the third resistor and the switching unit is grounded through the capacitor.

5. The circuit of claim 1, further comprising a fifth resistor connected between the cathode of second diode and the control terminal of the second electronic switch.

6. The circuit of claim 1, wherein the first and second electronic switches are n-channel field effect transistors.
